(19) United States
(12) Patent Application Publication
(10) Pub. No.: US 2026/0150585 A1
(43) Pub. Date: May 28, 2026

(54) MAGNETIC TUNNEL JUNCTION FREE LAYER OF MULTIPLE MAGNETIC MATERIALS

(71) Applicant: International Business Machines Corporation, Armonk, NY (US)

(72) Inventors: MATTHIAS GEORG GOTTWALD, Ridgefield, CT (US); Guohan Hu, Yorktown Heights, NY (US); John Bruley, Poughkeepsie, NY (US); Alexander Reznicek, Troy, NY (US)

(21) Appl. No.: 18/963,695

(22) Filed: Nov. 28, 2024

(51) Int. Cl. H10N 50/85; G11C 11/16; H10N 50/01; H10N 50/10

(52) U.S. Cl. CPC H10N 50/85; G11C 11/161; H10N 50/01; H10N 50/10

(57) ABSTRACT

A magnetic tunnel junction (MTJ) stack structure includes a reference layer, a tunnel barrier, and a free layer that includes multiple separate materials including a first material that exhibits greater than 100% tunnel magnetoresistance when paired with the tunnel barrier, and an ordered alloy material coupled to the first material. At least one part of the free layer is a ferromagnetic material.

### BACKGROUND

The present invention relates to the electrical, electronic, and computer arts, and more specifically, to magnetic tunnel junction (MTJ) stacks used in magnetoresistive random access memory (MRAM).

Magnetic tunnel junction stacks are suitable for use in various electronic applications, including non-volatile memory devices and magnetic field sensors. MRAM can, for example, offer faster operational speed than flash memory. MRAM devices may be able to replace dynamic random-access memory (DRAM) devices in some applications.

Magnetic tunnel junctions include two magnetic layers, and a tunnel barrier layer positioned between the magnetic layers. The magnetic layers can be characterized as “reference” and “free” layers, respectively, while the tunnel barrier can be a thin tunneling oxide layer, such as MgO. The magnetization direction of one layer of the junction is fixed so that it serves as the reference layer. An MTJ pillar can form an MRAM storage device. Such MRAM devices have two stable resistance states, corresponding to bits “0” and “1,” stored in an MRAM device as anti-parallel (AP) and parallel (P) orientation of the free layer with respect to the reference layer. The orientation of the magnetization of the free layer with respect to the reference layer can be determined by an electrical resistance measurement. Typically, anti-parallel alignment of the free layer with respect to the reference layer leads to high resistance. Parallel alignment of the free layer with respect to the reference layer leads to lower resistance than the anti-parallel alignment. Spin-polarized charge currents from the reference layer to the free layer or from the free layer to the reference layer causes the free layer to switch from parallel to anti-parallel orientation, with respect to the reference layer, or the other way around from anti-parallel to parallel orientation. Magnetic anisotropies create an energy barrier in between parallel and anti-parallel orientation of the free layer with respect to the reference layer. This energy barrier created by magnetic anisotropies ensures retention of the bit information stored in the MRAM device.

Spin torque transfer MRAM (STT-MRAM) design goals include fast write times (<10 nanoseconds (ns)), with an application of MRAM for last level cache memory or embedded dynamic random-access memory (eDRAM) replacement targeting about 2 ns write time. Sub 10 ns write times and meaningful data retention of a few years requires free layer materials with low magnetization and high perpendicular anisotropy. Further reading of the MRAM bit should also happen in less than 10 ns, which requires a sufficiently large resistance difference between the free layer being parallel to the reference layer or anti-parallel to the reference layer. The difference in resistance for the free and pinned layers being parallel (P) and anti-parallel (AP), is known as a tunnel magnetoresistance (TMR) ratio. For STT-MRAM, high perpendicular magnetic anisotropy (PMA) also is desirable to support a sufficient energy barrier at a low moment to assure data retention of the stored information. It is difficult to design magnetic tunnel junction (MTJ) stacks that can provide STT-MRAM devices with such fast switching times and high PMA.

Fabrication of MTJ stacks (or pillars) with ordered alloy free layers has typically required forming a thick multilayer seed layer stack including, for example, MnN and Coal having a combined thickness of about five hundred Angstroms. Alternatively, a relatively thick multilayer seed layer stack can include ScN, Cr, IrAl, and Coal. A free layer, a tunnel barrier, and a reference layer are formed over the seed layer. Crystalline MgO tunnel barriers grown on an amorphous layer can obtain an oriented (100) texture and provide a relatively high TMR (tunneling magnetoresistance) ratio. When using a magnetic tunnel junction as a storage device, the difference in the tunneling current, as the spin alignment of the free and pinned layers is switched between being parallel (P) and anti-parallel (AP), is known as a tunnel magnetoresistance (TMR) ratio.

### BRIEF SUMMARY

Principles of the invention provide techniques for a magnetic tunnel junction free layer of multiple magnetic materials. In one aspect, an exemplary magnetic tunnel junction (MTJ) stack structure includes a reference layer, a tunnel barrier, and a free layer that includes multiple separate materials including a first material that exhibits greater than 100% tunnel magnetoresistance when paired with the tunnel barrier, and an ordered alloy material coupled to the first material, in which at least one part of the free layer is a ferromagnetic material.

Another aspect provides a method for making a magnetic tunnel junction (MTJ) stack that has effective anisotropy field Hₖ>2.5T and tunnel magnetoresistance (TMR)>240% includes depositing an ordered alloy material of a free layer onto a Magnesium-Oxide (MgO) barrier layer, annealing to crystallize the ordered alloy material, depositing a Cobalt (Co) layer on the crystalline ordered alloy material, forming an intermetallic compound layer by annealing the Co layer and the crystalline ordered alloy material, and depositing a first material of the free layer onto the intermetallic compound layer that is epitaxially lattice matched to the intermetallic compound layer, the first material exhibiting greater than 100% tunnel magnetoresistance when paired with a tunnel barrier, in which the free layer includes multiple separate materials and at least one of the multiple separate materials is a ferromagnetic material.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action other than by performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 illustrates an example of a multi-layer free layer structure of a magnetic tunnel junction (MTJ) stack, according to exemplary embodiments.

FIG. 2 illustrates an example of a multi-layer free layer structure of a magnetic tunnel junction (MTJ) stack, according to exemplary embodiments.

FIGS. 3-6B illustrate precursor structures to the structures shown in FIGS. 1-2, according to exemplary embodiments.

FIG. 7 illustrates an Aluminum-Manganese-Germanium (AlMnGe) crystal structure, according to exemplary embodiments.

FIGS. 8A-8B illustrate precursor structures to the structures shown in FIGS. 1-2, according to exemplary embodiments.

FIG. 9 illustrates a tunneling electron microscope image of the structures shown in FIGS. 1-2, according to exemplary embodiments.

FIG. 10 illustrates a composition profile of the structure shown in FIG. 9, according to exemplary embodiments.

FIGS. 11-12 illustrate precursor structures to the structure shown in FIG. 1, according to exemplary embodiments.

FIG. 13 illustrates a completed magnetoresistive random access memory (MRAM) stack that includes the magnetic tunnel junction (MTJ) stack shown in FIG. 1, according to exemplary embodiments.

FIG. 14 illustrates a precursor structure to the structure shown in FIG. 2, according to exemplary embodiments.

FIGS. 15-16 illustrate a tunneling electron microscope images of the structures shown in FIG. 2, according to exemplary embodiments.

FIGS. 17-18 illustrate precursor structures to the structure shown in FIG. 2, according to exemplary embodiments.

FIG. 19 illustrates an example block diagram of the structure shown in FIG. 2, according to exemplary embodiments.

FIG. 20 illustrates a completed magnetoresistive random access memory (MRAM) stack that includes the magnetic tunnel junction (MTJ) stack shown in FIG. 2, according to exemplary embodiments.

FIG. 21 illustrates a tunnel magnetoresistance percentage (TMR %), in relation to a product of a resistance and area, graphical comparison between a magnetic tunnel junction (MTJ) using Aluminum-Manganese-Germanium (AlMnGe) and a magnetic tunnel junction (MTJ) using Cobalt-Aluminum-Manganese-Germanium (Coal(Mn:Ge)) and Cobalt-Iron (CoFe), of the exemplary embodiments.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, a magnetic tunnel junction (MTJ) stack 1000, 6000, 10000 includes a reference layer 6001, a tunnel barrier 1021, and a free layer 1001, 1003 that has multiple separate materials including a first material that exhibits greater than 100% tunnel magnetoresistance when paired with the tunnel barrier, and an ordered alloy material 1007 coupled to the first material, in which at least one part of the free layer 1001, 1003 is a ferromagnetic material. Technical benefits include combining the benefits of each layer of the MTJ 1000, 6000, 10000 to acquire a low magnetic moment for fast switching with a sufficiently high tunnel magnetoresistance (TMR).

Optionally, the ordered alloy material 1007 can include an Aluminum-Manganese-Germanium (AlMnGe) alloy 1007. In some options, the AlMnGe alloy 1007 can be in a 1:1:1 proportion. Technical benefits provide for a low moment with a high PMA, promoting data retention of the MRAM, by utilizing an AlMnGe alloy 1007 that exhibits high PMA characteristics.

Further, optionally, the tunnel barrier 1021 can include Magnesium-Oxide (MgO). Optionally, the first material can be selected from the group including Cobalt-Iron (CoFe) 1019 with less than 75% atomic Co and Iron (Fe) 1015. Optionally, the CoFe with less than 75% atomic Co can be a bilayer of Co and Fe. Further, optionally, the Fe 1015 of the free layer 1001 and the MgO of the tunnel barrier 1021 can have a common crystal structure. Technical benefits are a cubic material with a similar lattice constant to that of underlining layers allowing for the CoFe 1019 or the Fe 1015 to grow epitaxially onto a template and forming large crystallites through the first material into the tunnel barrier 1021, providing an environment for high PMA and high TMR qualities. Further, beneficially, a template for the MgO tunnel barrier 1021 and a high TMR is provided.

Continuing with options, a concentration of Fe in the free layer 1015 can be highest closest to the tunnel barrier 1021 and can fade as a distance from the tunnel barrier 1021 increases. Technical benefits are a formation of large epitaxial grains, providing an environment for high TMR qualities.

Optionally, the free layer 1003 can further include a layer of Cobalt-Aluminum (Coal) alloy 1017. In some options, the Coal 1017 can be in a 2:1 proportion. In optional further aspects, the ordered alloy material 1007 and the first material can be magnetically coupled, at least partially, by the layer of Coal 1017. A technical benefit is an improved Co-rich Coal 1017 template for the CoFe 1019 of the free layer 1003 improving crystallinity and yielding a higher TMR.

Continuing with options, the free layer 1001, 1003 can further include a layer of Cobalt (Co) 1011. Optionally, the ordered alloy material 1007 and the first material can be magnetically coupled, at least partially, by the layer of Co 1011. Technical benefits of a Cobalt capping layer 1011 is that the Cobalt becomes a well-ordered phase of Co—Al(Mn:Ge) 1013, forming an epitaxial template for following layers of the free layer 1001, 1003 and promoting coupling of the first material to the ordered alloy material 1007.

In further options, the materials within the free layer 1001, 1003 of the MTJ stack 1000, 6000, 10000 can have a common crystal structure. Technical benefits are combining the attributes of each layer of the free layer 1001, 1003 structure, such as high PMA, high TMR, low moment, for fast switching and improved data retention of the MRAM.

In optional further aspects, the free layer 1001, 1003 of the MTJ stack 1000, 6000, 10000 can have effective anisotropy field Hₖ>2.5T and tunnel magnetoresistance (TMR)>240%. Technical benefits include combining low moment and high PMA to yield fast switching speeds without jeopardizing integrity of the stored data, assuring fast and reliable data retention.

An aspect of an exemplary method of making a magnetic tunnel junction (MTJ) stack 1000, 6000, 10000 that has effective anisotropy field Hₖ>2.5T and tunnel magnetoresistance (TMR)>240% includes depositing an ordered alloy material 1007 of a free layer 1001, 1003 onto a Magnesium-Oxide (MgO) barrier layer 1005, annealing to crystallize the ordered alloy material 1007, depositing a Cobalt (Co) layer 1011 on the crystalline ordered alloy material 1009, forming an intermetallic compound layer 1013 by annealing the Co layer 1011 and the crystalline ordered alloy material 1009, and depositing a first material of the free layer 1001, 1003 onto the intermetallic compound layer 1013 that is epitaxially lattice matched to the intermetallic compound layer 1013, the first material exhibiting greater than 100% tunnel magnetoresistance when paired with a tunnel barrier, in which the free layer 1001, 1003 includes multiple separate materials and at least one of the multiple separate materials is a ferromagnetic material. Technical benefits include combining the benefits of each layer of the magnetic tunnel junction (MTJ) 1000, 6000, 10000 to acquire a low magnetic moment with a sufficiently high tunnel magnetoresistance (TMR) and a high PMA to yield fast switching speeds without jeopardizing integrity of the stored data, assuring fast and reliable MRAM data read and retention.

Optionally, the ordered alloy material 1007 can be a 1:1:1 proportioned Aluminum-Manganese-Germanium (AlMnGe) structure alloy 1007 and the intermetallic compound layer 1013 can be an epitaxial co-rich Coal alloy with Mn and Ge layer. Technical benefits provide for a low moment with a high PMA, promoting data retention of the MRAM, by utilizing an AlMnGe alloy 1007 that exhibits high PMA characteristics. Further, benefits of a Cobalt capping layer 1011 is that the Cobalt becomes a well-ordered phase of Co—Al(Mn:Ge) 1013, forming an epitaxial template for following layers of the free layer 1001, 1003 and promoting coupling of the first material to the ordered alloy material 1007.

In another option, the first material can be selected from the group including Co and Iron (Fe) 1019 with less than 75% atomic Co and a layer of Fe 1015. Technical benefits of CoFe 1019 are a cubic, first material with a similar lattice constant to that of underlining layers allowing for the CoFe 1019 to grow epitaxially onto a template and forming large epitaxial grains, providing a template for the MgO tunnel barrier 1021 to nucleate and grow, and resulting an environment yielding high TMR qualities. Further, technical benefits of a layer of Fe 1015 are a cubic material (Fe 1015) with a similar lattice constant to that of underlining layers allowing for the Fe 1015 to grow epitaxially onto a template and forming large crystallites.

In yet another option, the method can further include depositing the tunnel barrier of MgO 1021 over the free layer 1001, 1003 and depositing a reference layer 6001 over the tunnel barrier of MgO 1021. Technical benefits of depositing the tunnel barrier of MgO 1021 over the illustrated free layer 1001, 1003 embodiments is that the MgO can nucleate and grow in a better crystal quality than that of prior approaches.

In further options, a concentration of Fe in the free layer 1003 can be highest closest to the tunnel barrier 1021 and can fade as a distance from the tunnel barrier 1021 increases.

In optional further aspects, the CoFe 1019 can be preceded by a layer of Cobalt-Aluminum (Coal) 1017. Technical benefits are an improved uniformity and wetting of the first material, such as the CoFe 1019. Further, beneficially, the layer of Coal 1017 and the CoFe 1019 can provide a template for the MgO tunnel barrier 1021.

Techniques as disclosed herein can provide substantial beneficial technical effects. Some embodiments may not have these potential advantages, and these potential advantages are not necessarily required of all embodiments. By way of example only and without limitation, one or more embodiments can provide a Magnetic Tunnel Junction (MTJ) stack that has low magnetic moment for fast switching, with sufficiently high tunnel magnetoresistance (TMR) to enable a high data retention of stored bit information along with a fast and reliable read out of the stored bit information:
by forming a multi-layer free layer structure that combines the benefits of each single layer,
by forming a Coal(Mn:Ge) alloy coupling layer that is cubic and magnetic, couples the first part of a free layer, is an epitaxial template and enables formation of a second part of the magnetically coupled free layer,
by improving crystallinity yields,
by forming large epitaxial grains from an Fe layer that is similar to the lattice constant of underlying stack layers, and/or
by having a free layer with an epitaxial relationship that spreads continuously through a free layer and into a tunnel barrier.

In MTJ stacks, it has been found that tetragonal Aluminum-Manganese-Germanium (AlMnGe) (1:1:1) offers low magnetic moment and high PMA (Hₖ of 3-5 Tesla), but observed tunnel magnetoresistance (TMR) is relatively low (15-25%), due to low spin polarization of C38 structure alloys such as AlMnGe. Low TMR means a smaller relative resistance difference between the parallel and antiparallel respective orientations of the free and reference layers, and therefore a small read signal. This makes fast memory readout challenging. Additionally, growing coupled multi-layer free layer structures containing AlMnGe is challenging, as lattice fitting magnetic materials, such as other ordered alloys (e.g., Heusler alloys), do not easily nucleate or grow on AlMnGe surfaces. One approach to achieving high perpendicular magnetic anisotropy (PMA) and high tunnel magnetoresistance (TMR) for free layers containing AlMnGe includes forming multi-layer free layer structures that combine the benefits of each single layer. For example, though Iron (Fe) or Cobalt-Iron (CoFe) have low anisotropy, they do have high spin polarization (e.g., greater than 100% tunnel magnetoresistance when paired with the tunnel barrier) and provide high TMR, and AlMnGe provides high PMA. Thus, both structural elements together can provide a combination of high PMA and high TMR in the multi-layer free layer structure.

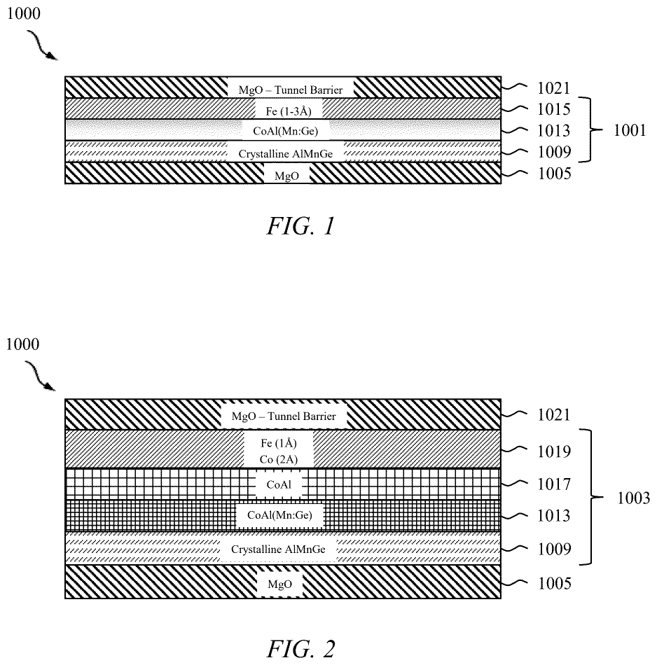

Accordingly, FIG. 1 illustrates an inventive magnetic tunnel junction (MTJ) stack structure 1000, according to exemplary embodiments, in which a first Magnesium-Oxide (MgO) tunnel barrier layer 1021 and a second MgO barrier layer 1005 sandwich a free layer 1001 including an Fe layer 1015 and a crystalline AlMnGe layer 1009 that are coupled by a Coal(Mn: Ge) layer 1013. Further, FIG. 2 illustrates an inventive magnetic tunnel junction (MTJ) stack structure 1000, according to exemplary embodiments, in which a first MgO tunnel barrier layer 1021 and a second MgO barrier layer 1005 sandwich an alternative free layer 1003 including CoFe 1019 and a crystalline AlMnGe layer 1009 that are coupled by a Coal(Mn: Ge) layer 1013. The CoFe 1019 can be a bilayer of CoFe, in some embodiments. Optionally, the free layer 1003 can further include a Cobalt-Aluminum (Coal) layer 1017 that further couples the CoFe 1019 and the crystalline AlMnGe layer 1009. The MTJ stack structure 1000 can be a ferrimagnetic system.

Although conventionally it has been prohibitively hard to form multi-layer free layers that incorporate a C38 crystalline substance such as AlMnGe, according to exemplary embodiments, a method of depositing a cobalt (Co) seed layer onto a crystallized AlMnGe layer 1009, and then annealing that structure, forms a complex surface compound—Coal(Mn:Ge)—that allows epitaxial growth of other alloys, such as Fe and CoFe. Cobalt is a magnetic layer, which enables growth of high spin polarization materials (e.g., 100% spin polarization) or materials that exhibit greater than 100% tunnel magnetoresistance when paired with a tunnel barrier such as Fe and CoFe onto AlMnGe, and which also magnetically couples the Fe or CoFe to the AlMnGe. With the Co seed layer, the Fe or CoFe alloy can be grown with lattice matching to the underlying stack (AlMnGe) and the entire stack can be switched together. Generally, other C38 alloys (e.g., MnGaSi, MgMnGe, MnGaGe) can be used in place of AlMnGe if they are compatible; i.e., will form an alloy, with cobalt.

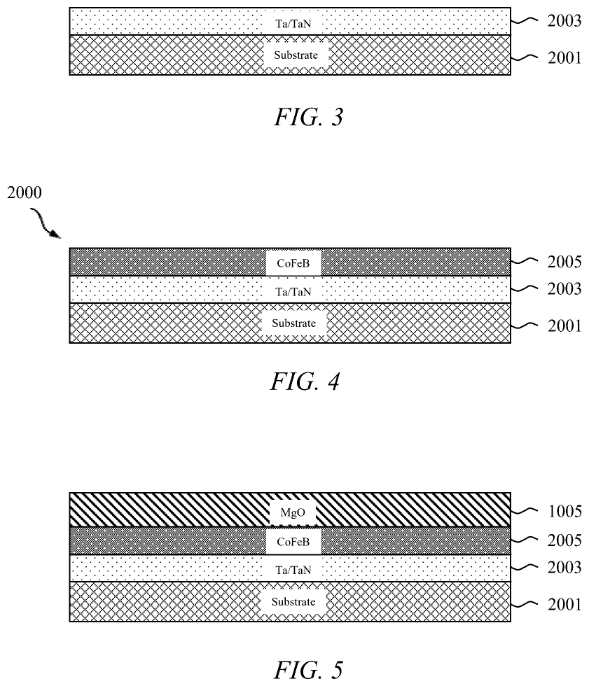

As shown in FIG. 3, a magnetic tunnel junction (MTJ) stack structure can include a silicon substrate 2001 with amorphous Tantalum/Tantalum-Nitride (Ta/TaN) layer 2003 overtop. FIG. 4 shows a Cobalt-Iron-Boron (CoFeB) layer 2005 deposited over the substrate 2001 and the Ta/TaN layer 2003 forming a first portion 2000 (i.e., a template) of the MTJ stack structure. The Ta/TaN layer 2003 and the CoFeB layer 2005 can be amorphous at this stage of deposition. It will be noted that the amorphous layers only need to be amorphous upon deposition and during subsequent deposition of an MgO barrier layer (or seed layer) as described below. The amorphous template layer can crystallize later in the process, such that the final structure can include a crystalline layer beneath the MgO barrier layer.

Referring to FIG. 5, a MgO barrier layer 1005 can be deposited over the CoFeB layer 2005 located above the Ta/TaN layer 2003 and the substrate 2001. The MgO barrier layer 1005 can be a seed layer and the CoFeB layer 2005, Ta/TaN layer 2003, and substrate 2001 can be a template layer of the MTJ stack structure. When MgO is deposited onto an amorphous CoFeB layer 2005, it naturally forms a highly textured (001) oriented crystalline structure by itself. MgO has a cubic (NaCl-like) structure with a lattice constant of 4.25 Å.

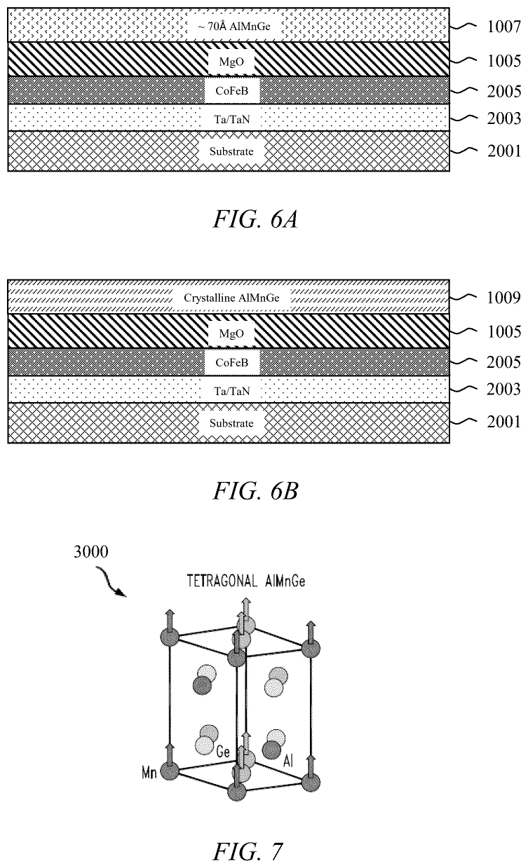

As shown in FIG. 6A, a first part 1007 of a free layer can be deposited onto the MgO barrier layer 1005. The first part 1007 of the free layer can be an amorphous AlMnGe alloy (in one or more embodiments, 60-80 Å thick). In one or more embodiments, the deposited AlMnGe can be about 2-10 Å thicker than a final desired amount to allow for some consumption in subsequent steps, when the excess material will react with deposited 5 Å thickness (a non-limiting example) of cobalt to form the seed or coupling layer. After deposition, the first part 1007 of the free layer can be annealed inside an ultrahigh vacuum (UHV) system to crystallize the C38 alloy into its tetragonal lattice phase (crystalline AlMnGe (˜70 Å) 1009), as shown in FIG. 6B. In embodiments that use AlMnGe, the square bottom plane of the tetragonal AlMnGe has a lattice constant of 3.9 Å, which aligns to the (001) textured MgO crystallites and forms a textured AlMnGe. FIG. 7 shows the tetragonal crystal lattice 3000 of AlMnGe.

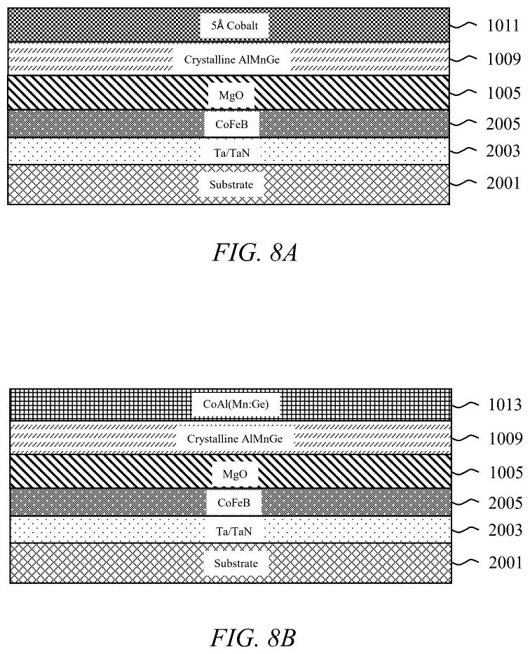

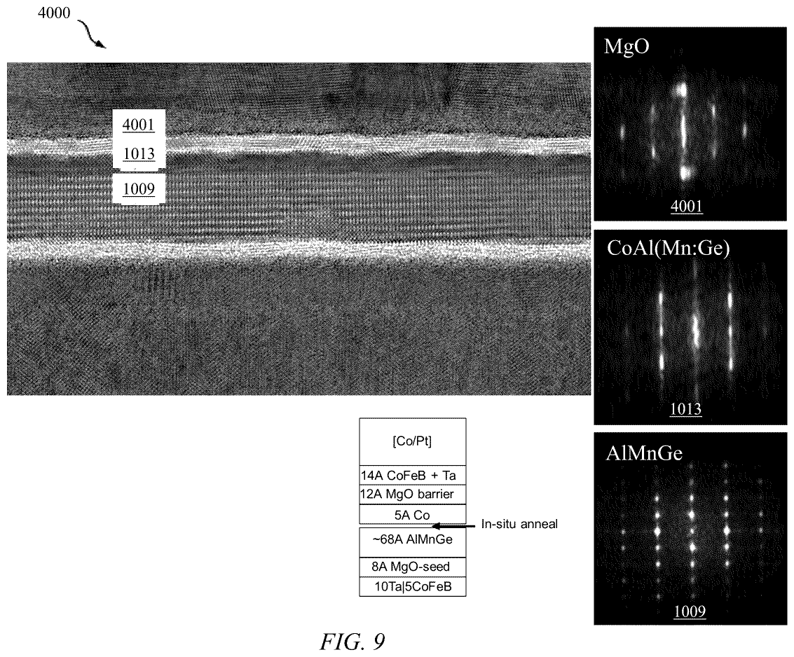

Referring to FIG. 8A, a thin layer (in a non-limiting example, 5 Å) of cobalt 1011 (which provides a magnetic coupling seed for the second part of the free layer) can be deposited over the crystalline AlMnGe layer 1009. The cobalt 1011 is a capping layer that can be a well-ordered phase on the AlMnGe, with near-perfect crystallinity. Afterwards, the thin Cobalt layer 1011 is annealed on the crystalline AlMnGe layer 1009 in the UHV system. As shown in FIG. 8B, the cobalt can react with the AlMnGe layer and can form an epitaxial cobalt-rich layer 1013 of Coal alloyed with Mn and Ge which aligns to the quadratic surface crystallinity of the AlMnGe 1009 as shown in the test structure 4000 of FIG. 9. FIG. 9 also shows a layer 4001 of MgO, which, in one or more embodiments, is not part of the inventive structure; FIG. 9 is merely illustrative of a test structure 4000 that demonstrates the epitaxial crystal structure that is achievable by exemplary embodiments of the disclosure. The formed Coal(Mn:Ge) alloy layer 1013 is cubic, magnetic, and can bridge the lattice constant. The Mn and Ge of the Coal(Mn:Ge) alloy layer 1013 can be approximately 20-25 percent of the atoms within the Coal(Mn:Ge) alloy layer 1013. The reacted cobalt spacer can magnetically couple the crystalline AlMnGe 1009 to a second part of the free layer and can also enable epitaxial growth of the second part of the magnetically coupled free layer.

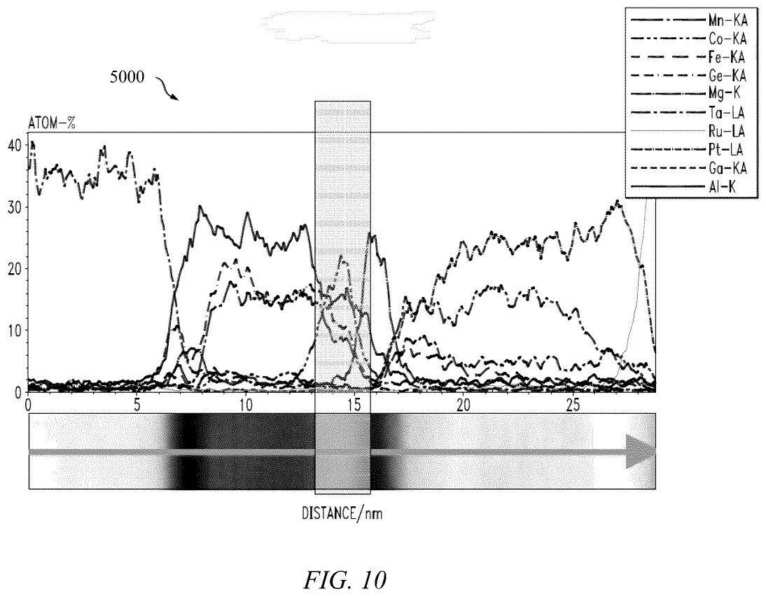

FIG. 10 illustrates a graph 5000 that shows relative proportions of metallic composition at various layers of the structure shown in FIG. 9. The left side of the graph in FIG. 10 corresponds to the bottom of the structure in FIG. 9 and the right side of the graph in FIG. 10 corresponds to the top of the structure in FIG. 9. The vertical box in the middle of FIG. 10 corresponds to the coupling layer 1013.

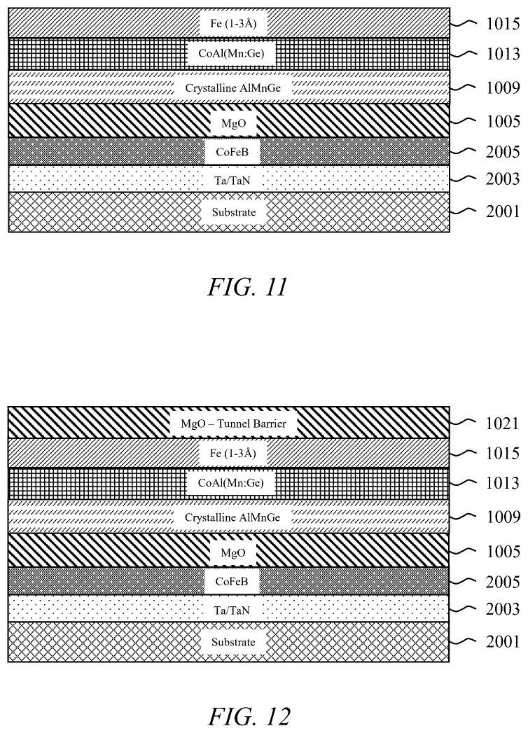

Referring to FIG. 11, in one or more embodiments, a second part of the free layer that includes Iron (Fe) (e.g., 1-3 Å) 1015 can be deposited onto the Coal(Mn:Ge) layer 1013. Fe is cubic and has a lattice parameter of 2.87 Å. If the unit cell of the cubic Fe is rotated 45 degrees, the lattice spacing in the (011) direction is 4.05 Å, which is similar to the lattice constant of 3.9 Å of the underlying stack layers. The iron can grow epitaxially onto the template, forming large crystallites. The large crystallites can result in the observance of high magnetoresistance. The cobalt-rich surface 110 enables the growth of the epitaxial cubic Fe 1015 in the second part of the free layer. In a non-limiting example, there is no annealing step directly after the Fe deposition, but the Fe will be exposed to annealing steps later during processing as any other part of the MRAM stack.

As shown in FIG. 12, an MgO tunnel barrier layer 1021 can be deposited over the Fe layer 1015. The MgO will nucleate and grow and has a cubic structure with a lattice constant of 4.25 Å. The cubic structure aligns well with the 45 degrees rotated unit cell of the cubic Fe, which has a lattice spacing of 4.05 Å in the (011) direction. Due to the close lattice match, large MgO crystallites are formed. The interface between the materials, Fe, and MgO can lead to high TMR. Note that the MgO can have random in-plane orientations; in one or more embodiments, a pertinent aspect for a good (high TMR) tunnel barrier is that the MgO grains all have the same (001) orientation perpendicular to the film planes; in-plane orientations are not relevant in one or more embodiments.

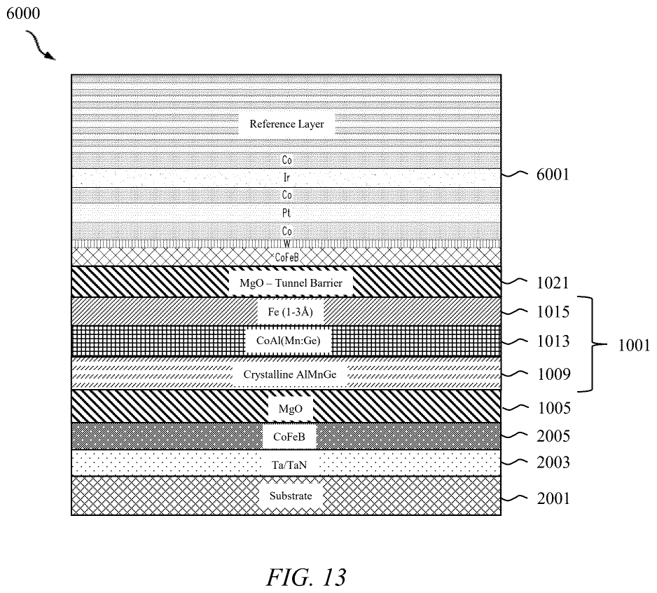

Referring to FIG. 13, the MTJ stack structure 6000 is finished with a reference layer 6001. The ordinary skilled worker is well-acquainted with reference layers in MRAM, and, given the teachings herein, can adapt known techniques to fabricate one or more embodiments. For example, an exemplary reference layer can include multiple layers, including a pinning layer, ferromagnetic layers, and a spacer layer between the ferromagnetic layers. When a bias is applied to the MTJ device, electrons that are spin polarized by the magnetic layers tunnel through the tunnel barrier between the magnetic layers, through a process known as quantum tunneling, to generate an electric current, the magnitude of which depends on an orientation of magnetization of the magnetic layers. The MTJ device will exhibit a low resistance when a magnetic moment of the free layer is parallel to the fixed (reference) layer magnetic moment, and it will exhibit a high resistance when the magnetic moment of the free layer is oriented anti-parallel to the fixed layer magnetic moment.

Accordingly, in one or more embodiments, as shown in FIG. 13, a finished MTJ stack structure 6000 can include the reference layer 6001, a tunnel barrier 1021, a free layer 1001 that includes a first material that exhibits greater than 100% tunnel magnetoresistance when paired with the tunnel barrier, such as a layer of Fe 1015, and an ordered alloy material, such as a crystalline AlMnGe alloy layer 1009, coupled by a layer of Co annealed to form an epitaxial Co-rich Coal alloy with Mn and Ge 1013, an MgO barrier layer 1005, a CoFeB layer 2005, a Ta/TaN layer 2003, and a substrate 2001. The free layer 1001 can include magnetic materials within all layers of the free layer 1001. Further, the MTJ stack structure 6000 can have an epitaxial relationship that spreads continuously from the ordered alloy 1009 (e.g., crystalline AlMnGe), through the free layer 1001, and into the MgO tunnel barrier 1021, combining high PMA and high TMR for fast switching of MRAM.

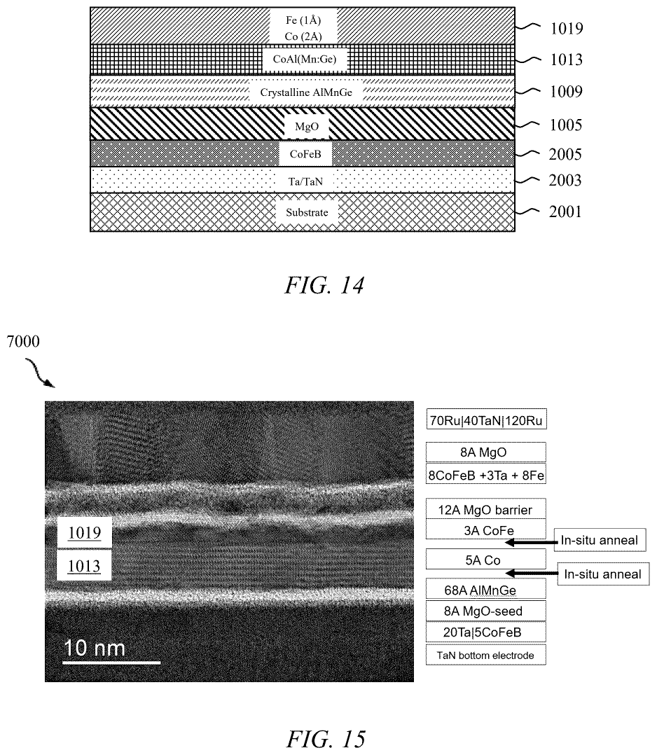

Turning now to FIG. 14, alternatively, in one or more embodiments, the second part of the free layer that includes CoFe 1019 can be deposited onto the Coal(Mn: Ge) layer 1013. The CoFe 1019 can be a bilayer of CoFe, in some embodiments. The thickness of the bilayer of CoFe 1019 can be, e.g., 3 Å. For example, the thickness of the Co can be 2 Å and the thickness of the Fe can be 1 Å, though examples are not so limited (e.g., the thickness of the Fe can be 2 Å and the thickness of the Co can be 1 Å). In some embodiments, the combination of cobalt and iron (CoFe) can lead to a higher observed TMR than embodiments with Fe as the second part of the free layer alone. An improved crystallite formation of the CoFe alloy atop the Co-rich Coal alloy with Mn and Ge 1013 surface can be observed in comparison to an Fe only layer. In some embodiments, the Fe can be on top of the Co in the bilayer (in closer proximity to the MgO tunnel barrier) to provide for a template for the MgO tunnel barrier and a high TMR. In some embodiments, at least 20 percent of the CoFe alloy can be Fe. As shown in the test structure 7000 in FIG. 15, the bilayer of CoFe 1019 can grow epitaxially aligning well onto the cubic Coal(Mn: Ge) layer 1013. FIG. 15 is merely an illustrative example of the test structure 7000 that demonstrates that after the stack is annealed, an Al-rich AlCoFe region with a cubic crystallography can be observed at the Coal(Mn: Ge)/CoFe interface. This crystallographic matching, in conjunction with remaining high spin polarizing bilayer of CoFe 1019 exhibiting greater than 100% tunnel magnetoresistance and a well-formed MgO tunnel barrier, can lead to a very high TMR in the resulting MRAM stack. Further, the CoFe (or any other magnetic alloy) can thus be magnetically coupled to the ordered alloy AlMnGe.

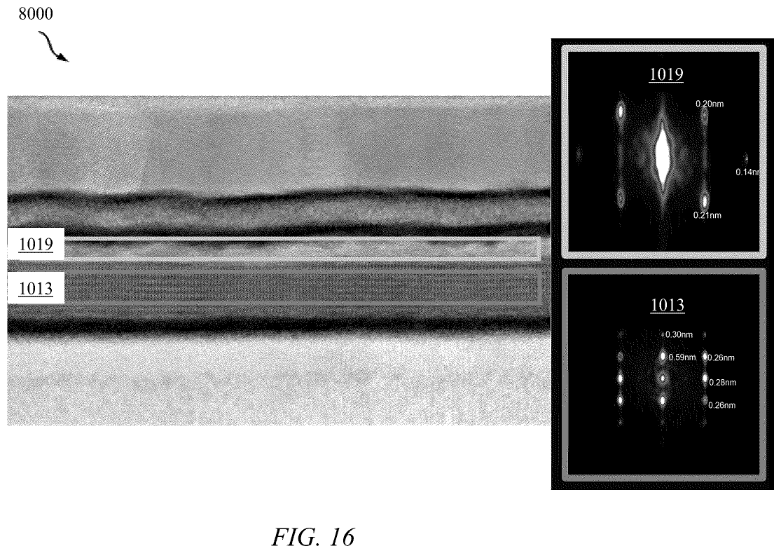

FIG. 16 illustrates a fast Fourier transform (FFT) analysis 8000 of regions of the Co and CoFe cap and the Coal(Mn:Ge) layer 1013. Specifically, FIG. 16 illustrates that the CoFe 1019 has a single crystal epitaxial structure and is in-plane lattice matched to the Coal(Mn:Ge) layer 1013.

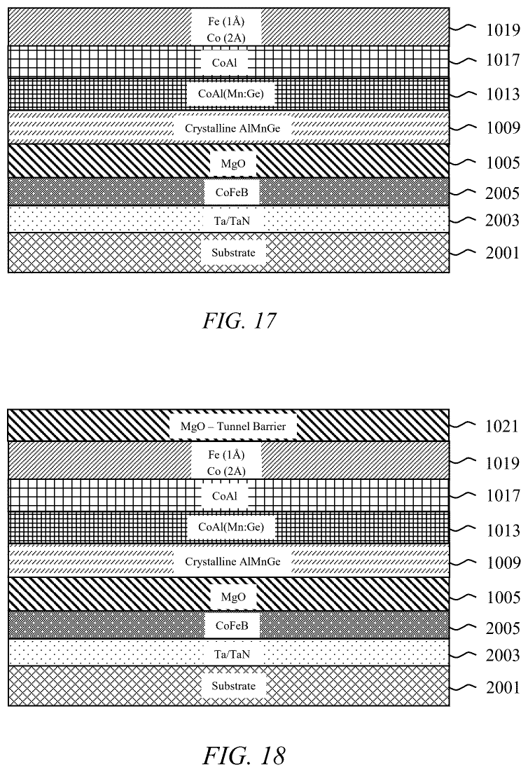

Optionally, a thin layer of Coal 1017 can be deposited on the Coal(Mn: Ge) layer 1013 prior to depositing of the CoFe 1019, as shown in FIG. 17. The Co: Al ratio can be 2:1. For example, the ratio can be 2 Å of Co and 1 Å of Al or the ratio can be 1 Å of Co+1 Å of Al+1 Å of Co. The additional Coal layer 1017 can lead to an improved crystallite formation of the CoFe alloy as the Coal layer 1017 can improve uniformity and wetting of the CoFe 1017 to the layers below. As such, the optional Coal layer 1017 can be part of the coupling layer, coupling the Coal(Mn:Ge) layer 1013 to the CoFe 1019.

As shown in FIG. 18, an MgO tunnel barrier layer 1021 can be deposited over the CoFe 1019. The MgO will nucleate and grow and has a cubic structure with a lattice constant of 4.25 Å. The cubic structure aligns well with the 45 degrees rotated unit cell of the cubic Fe of the CoFe 1019, which has a lattice spacing of 4.05 Å in the (011) direction. Due to the close lattice match, large MgO crystallites are formed. The interface between the materials, the Fe of the CoFe 1019, and MgO can lead to high TMR. Note that the MgO can have random in-plane orientations; in one or more embodiments, a pertinent aspect for a good (high TMR) tunnel barrier is that the MgO grains all have the same (001) orientation perpendicular to the film planes; in-plane orientations are not relevant in one or more embodiments.

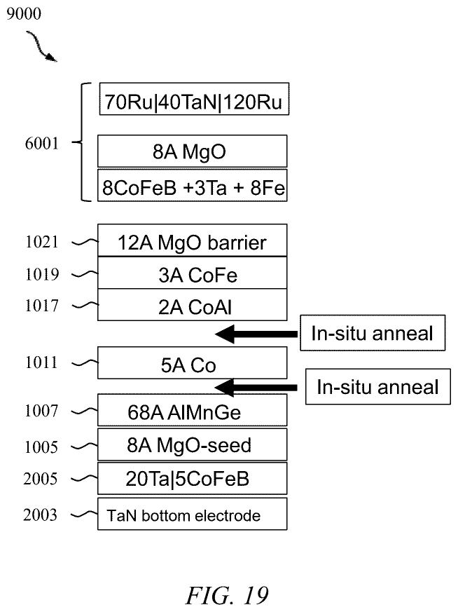

Accordingly, FIG. 19 illustrates one example of material and/or layer thicknesses within an MTJ stack structure 9000, although examples are not so limited and such thickness can be approximated or within a percentage or range. In one or more embodiments, the barrier layer (i.e., seed layer) and the tunnel barrier of MgO of the MJT stack structure 9000 can be between 8 Å and 14 Å thick. An AlMnGe layer 1007 can be between 15 Å and 100 Å thick. Further, a Co layer can be between 2 Å and 8 thick Å. An optional layer of Coal can be 1-5 Å thick. Additionally, a CoFe or a bilayer of CoFe can be between 3 Å and 10 Å thick. As a non-limiting example, the MTJ stack structure 9000 can include, at least in part, an 8 Å thick barrier layer (i.e., seed layer) of MgO 1005, a 68 Å thick AlMnGe layer 1007, a 5 Å thick layer of Co 1011, an optional 2 Å thick layer of Coal 1017, a 3 Å thick layer of CoFe 1019, and a 12 Å thick MgO tunnel barrier 1021.

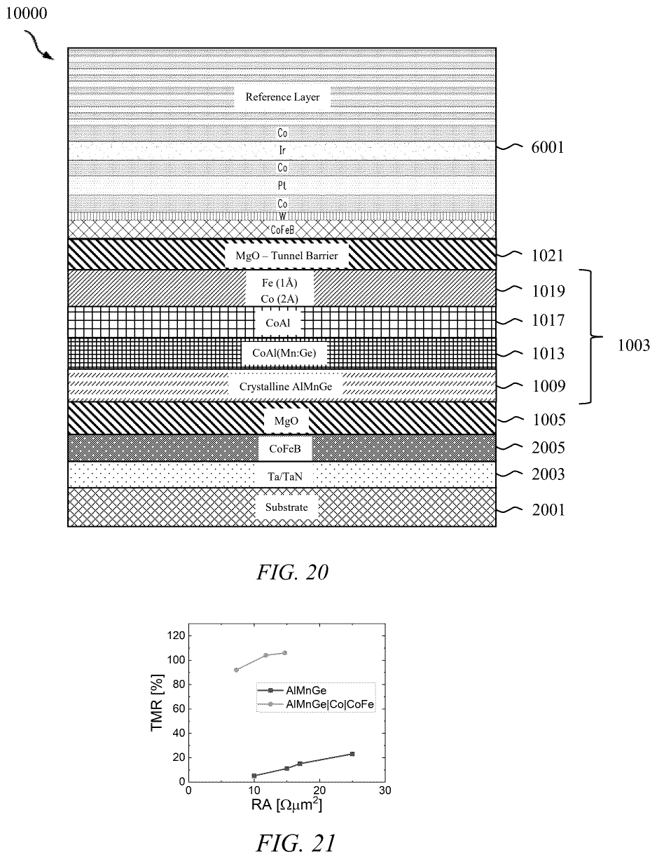

Referring now to FIG. 20, in one or more embodiments, the MTJ stack structure 10000 is finished with a reference layer 6001. As previously stated, the ordinary skilled worker is well-acquainted with reference layers in MRAM, and, given the teachings herein, can adapt known techniques to fabricate one or more embodiments. For example, an exemplary reference layer can include multiple layers, including a pinning layer, ferromagnetic layers, and a spacer layer between the ferromagnetic layers. When a bias is applied to the MTJ device, electrons that are spin polarized by the magnetic layers tunnel through the tunnel barrier between the magnetic layers, through a process known as quantum tunneling, to generate an electric current, the magnitude of which depends on an orientation of magnetization of the magnetic layers. The MTJ device will exhibit a low resistance when a magnetic moment of the free layer is parallel to the fixed (reference) layer magnetic moment, and it will exhibit a high resistance when the magnetic moment of the free layer is oriented anti-parallel to the fixed layer magnetic moment.

Accordingly, in one or more embodiments, as shown in FIG. 20, a finished MTJ stack structure 10000 can include the reference layer 6001, a tunnel barrier 1021, and a free layer 1003. Free layer 1003 can include a first material that exhibits greater than 100% tunnel magnetoresistance when paired with the tunnel barrier, such as CoFe 1019, and an ordered alloy material, such as a crystalline AlMnGe alloy layer 1009, coupled by a layer of Co annealed to form an epitaxial Co-rich Coal alloy with Mn and Ge 1013, optionally, further coupled by a layer of Coal 1017 for potential improvements in wetting and uniformity. Finished MTJ stack structure 10000 can also include an MgO barrier layer 1005, a CoFeB layer 2005, a Ta/TaN layer 2003, and a substrate 2001. The free layer 1003 can include magnetic materials within all layers of the free layer 1003. Further, the MTJ stack structure 10000 can have an epitaxial relationship that spreads continuously from the ordered alloy 1009 (e.g., AlMnGe), through the free layer 1003, and into the MgO tunnel barrier 1021, combining high PMA and high TMR for fast switching MRAM.

Turning now to FIG. 21, an experimental data graph is shown, indicating a value of tunnel magnetoresistance percentage, shown on the left-hand side of the graph as TMR [%], in relation to a product of a resistance and area, shown on the bottom of the graph as RA [Ωμm²]. Particularly, the graph indicates a difference in TMR to the product of the resistance and area in an MTJ stack structure utilizing AlMnGe vs. the significant improvement in TMR in an MTJ stack structure utilizing Coal(Mn: Ge) and CoFe. The use of Coal(Mn: Ge) and CoFe alloys can contribute at a much higher spin polarization than AlMnGe alone, resulting in the higher range of TMR.

MTJ stack films can be deposited using, for example, physical vapor deposition (PVD), ion beam deposition (IBD) or other techniques. In one or more embodiments, layers of the MTJ stack are deposited epitaxially. “Epitaxial” deposition means the growth of a material on a deposition surface in which the material being grown has the same crystalline characteristics as the deposition surface. In an epitaxial deposition process, the chemical reactants are controlled and the system parameters are set so that the atoms being deposited arrive at the deposition surface of the semiconductor substrate with sufficient energy to move around on the surface and orient themselves to the crystal arrangement of the atoms of the deposition surface.

The drawing figures as discussed above depict exemplary processing steps/stages in the fabrication of exemplary structures. Although the overall fabrication methods and the structures formed thereby are entirely novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices or other layers may not be explicitly shown in a given figure for ease of explanation. This does not imply that the semiconductor layer(s) or other layer(s) not explicitly shown are omitted in the actual integrated circuit device.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

At least a portion of the techniques described above may be implemented in an integrated circuit. Forming integrated circuits, identical dies are typically fabricated in a repeated pattern on a surface of a semiconductor wafer. Each die includes a device described herein and may include other structures and/or circuits. The individual dies are cut or diced from the wafer, then packaged as an integrated circuit. One skilled in the art would know how to dice wafers and package die to produce integrated circuits.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from having structures such as memory devices including magnetic tunnel junctions formed in accordance with one or more of the exemplary embodiments.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom,” “top,” “above,” “over,” “under,” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

What is claimed is:

1. A magnetic tunnel junction (MTJ) stack structure, comprising:
a reference layer;
a tunnel barrier; and
a free layer that comprises multiple separate materials including:
a first material that exhibits greater than 100% tunnel magnetoresistance when paired with the tunnel barrier; and
an ordered alloy material coupled to the first material,
wherein at least one part of the free layer is a ferromagnetic material.

2. The structure of claim 1, wherein the ordered alloy material comprises an Aluminum-Manganese-Germanium (AlMnGe) alloy.

3. The structure of claim 2, wherein the AlMnGe alloy is in 1:1:1 proportion.

4. The structure of claim 1, wherein the tunnel barrier comprises Magnesium-Oxide (MgO).

5. The structure of claim 4, wherein the first material is selected from the group consisting of:
Cobalt-Iron (CoFe) with less than 75% atomic Co; and
Iron (Fe).

6. The structure of claim 5, wherein the CoFe with less than 75% atomic Co is a bilayer of Co and Fe.

7. The structure of claim 5, wherein the Fe of the free layer and the MgO of the tunnel barrier have a common crystal structure.

8. The structure of claim 5, wherein a concentration of Fe in the free layer is highest closest to the tunnel barrier and fades as a distance from the tunnel barrier increases.

9. The structure of claim 5, wherein the free layer further comprises a layer of Cobalt-Aluminum (Coal) alloy.

10. The structure of claim 9, wherein the Coal is in 2:1 proportion.

11. The structure of claim 9, wherein the ordered alloy material and the first material are magnetically coupled, at least partially, by the layer of Coal.

12. The structure of claim 1, wherein the free layer further comprises a layer of Cobalt (Co) and the ordered alloy material and the first material are magnetically coupled, at least partially, by the layer of Co.

13. The structure of claim 1, wherein the materials within the free layer of the MTJ stack have a common crystal structure.

14. The structure of claim 1, wherein the free layer of the MTJ stack has effective anisotropy field Hₖ>2.5T and tunnel magnetoresistance (TMR)>240%.

15. A method for making a magnetic tunnel junction (MTJ) stack that has effective anisotropy field Hₖ>2.5T and tunnel magnetoresistance (TMR)>240%, the method comprising:
depositing an ordered alloy material of a free layer onto a Magnesium-Oxide (MgO) barrier layer;
annealing to crystallize the ordered alloy material;
depositing a Cobalt (Co) layer on the crystalline ordered alloy material;
forming an intermetallic compound layer by annealing the Co layer and the crystalline ordered alloy material; and
depositing a first material of the free layer onto the intermetallic compound layer that is epitaxially lattice matched to the intermetallic compound layer, the first material exhibiting greater than 100% tunnel magnetoresistance when paired with a tunnel barrier,
wherein the free layer comprises multiple separate materials and at least one of the multiple separate materials is a ferromagnetic material.

16. The method of claim 15, wherein the ordered alloy material is a 1:1:1 proportioned Aluminum-Manganese-Germanium (AlMnGe) structure alloy and the intermetallic compound layer is an epitaxial co-rich Coal alloy with Mn and Ge layer.

17. The method of claim 15, wherein the first material is selected from the group consisting of:
Co and Iron (Fe) with less than 75% atomic Co; and
a layer of Fe.

18. The method of claim 17, further comprising:
depositing the tunnel barrier of MgO over the free layer; and
depositing a reference layer over the tunnel barrier of MgO.

19. The method of claim 18, wherein a concentration of Fe in the free layer is highest closest to the tunnel barrier and fades as a distance from the tunnel barrier increases.

20. The method of claim 17, wherein the CoFe is preceded by a layer of Cobalt-Aluminum (Coal).
